(19) United States
(12) Patent Application Publication
(10) Pub. No.: US 2024/0268121 A1
(43) Pub. Date: Aug. 8, 2024

(54) SEMICONDUCTOR MEMORY DEVICE

(71) Applicant: Kioxia Corporation, Tokyo (JP)

(72) Inventors: Masaharu MIZUTANI, Yokkaichi (JP); Masao SHINGU, Yokkaichi (JP); Kensei TAKAHASHI, Kuwana (JP)

(73) Assignee: Kioxia Corporation, Tokyo (JP)

(21) Appl. No.: 18/595,731

(22) Filed: Mar. 5, 2024

Related U.S. Application Data
(63) Continuation of application No. PCT/JP2021/045569, filed on Dec. 10, 2021.

(30) Foreign Application Priority Data
Sep. 9, 2021 (JP) 2021-146796

(51) Int. Cl. H10B 43/35; H10B 43/27

(52) U.S. Cl. CPC H10B 43/35; H10B 43/27

(57) ABSTRACT

A semiconductor memory device according to an embodiment includes: a semiconductor layer extending in a first direction; a gate electrode layer including at least one metal element selected from a group consisting of tungsten (W), molybdenum (Mo), and cobalt (Co); a charge storage layer provided between the semiconductor layer and the gate electrode layer; and a first insulating layer provided between the charge storage layer and the gate electrode layer, the first insulating layer including a first region, the first region including aluminum (Al) and oxygen (O), the first insulating layer being in contact with the gate electrode layer.

### CROSS-REFERENCE TO RELATED APPLICATION

This application is continuation application of, and claims the benefit of priority from Japanese Patent Application No. 2021-146796, filed on Sep. 9, 2021, and the International Application PCT/JP2021/045569, filed on Dec. 10, 2021, the entire contents of which are incorporated herein by reference.

### FIELD

Embodiments of the present invention relate to semiconductor memory devices.

### BACKGROUND

A three-dimensional NAND flash memory in which memory cells are arranged three-dimensionally achieves a high degree of integration and a low cost. In the three-dimensional NAND flash memory, for example, a memory hole is formed in a stacked body, in which a plurality of insulating layers and a plurality of gate electrode layers are alternately stacked, to penetrate the stacked body. A charge storage layer and a semiconductor layer are formed in the memory hole to form a memory string in which a plurality of memory cells are connected in series. The amount of charge held in the charge storage layer is controlled to store data in the memory cell.

### BRIEF DESCRIPTION OF THE DRAWINGS

FIG. 1 is a circuit diagram illustrating a memory cell array of a semiconductor memory device according to a first embodiment;

FIGS. 2A and 2B are a schematic cross-sectional view illustrating the memory cell array of the semiconductor memory device according to the first embodiment;

FIG. 3 is a schematic cross-sectional view illustrating a memory cell of the semiconductor memory device according to the first embodiment;

FIG. 4 is a schematic cross-sectional view illustrating an example of a method for manufacturing the semiconductor memory device according to the first embodiment;

FIG. 5 is a schematic cross-sectional view illustrating an example of the method for manufacturing the semiconductor memory device according to the first embodiment;

FIG. 6 is a schematic cross-sectional view illustrating an example of the method for manufacturing the semiconductor memory device according to the first embodiment;

FIG. 7 is a schematic cross-sectional view illustrating an example of the method for manufacturing the semiconductor memory device according to the first embodiment;

FIG. 8 is a schematic cross-sectional view illustrating an example of the method for manufacturing the semiconductor memory device according to the first embodiment;

FIG. 9 is a schematic cross-sectional view illustrating an example of the method for manufacturing the semiconductor memory device according to the first embodiment;

FIG. 10 is a schematic cross-sectional view illustrating an example of the method for manufacturing the semiconductor memory device according to the first embodiment;

FIG. 11 is a schematic cross-sectional view illustrating an example of the method for manufacturing the semiconductor memory device according to the first embodiment;

FIG. 12 is a schematic cross-sectional view illustrating an example of the method for manufacturing the semiconductor memory device according to the first embodiment;

FIG. 13 is a schematic cross-sectional view illustrating an example of the method for manufacturing the semiconductor memory device according to the first embodiment;

FIG. 14 is a schematic cross-sectional view illustrating an example of the method for manufacturing the semiconductor memory device according to the first embodiment;

FIG. 15 is a schematic cross-sectional view illustrating a memory cell of a semiconductor memory device according to a comparative example of the first embodiment;

FIGS. 16A and 16B are a schematic cross-sectional view illustrating a memory cell array of a semiconductor memory device according to a second embodiment;

FIG. 17 is a schematic cross-sectional view illustrating a memory cell of the semiconductor memory device according to the second embodiment;

FIG. 18 is a schematic cross-sectional view illustrating an example of a method for manufacturing the semiconductor memory device according to the second embodiment;

FIG. 19 is a schematic cross-sectional view illustrating an example of the method for manufacturing the semiconductor memory device according to the second embodiment; and

FIG. 20 is a schematic cross-sectional view illustrating a memory cell of a semiconductor memory device according to a comparative example of the second embodiment.

### DETAILED DESCRIPTION

A semiconductor memory device according to an embodiment includes: a semiconductor layer extending in a first direction; a gate electrode layer including at least one metal element selected from a group consisting of tungsten (W), molybdenum (Mo), and cobalt (Co); a charge storage layer provided between the semiconductor layer and the gate electrode layer; and a first insulating layer provided between the charge storage layer and the gate electrode layer, the first insulating layer including a first region, the first region including aluminum (Al) and oxygen (O), the first insulating layer being in contact with the gate electrode layer.

Hereinafter, embodiments of the invention will be described with reference to the drawings. In addition, in the following description, the same or similar members and the like are denoted by the same reference numerals, and a description of members and the like that have already been explained will be omitted as appropriate.

Further, in this specification, the term “upper side” or “lower side” may be used for convenience. The “upper side” or the “lower side” is, for example, a term indicating a relative positional relationship in the drawings. The term “upper side” or “lower side” does not necessarily define the positional relationship with respect to gravity.

Qualitative analysis and quantitative analysis of chemical compositions of members constituting a semiconductor memory device in the specification can be performed by, for example, secondary ion mass spectroscopy (SIMS), energy dispersive X-ray spectroscopy (EDX), electron energy loss spectroscopy (EELS), and the like. Further, for example, a transmission electron microscope (TEM) can be used to measure the thickness of the members constituting the semiconductor memory device, the distance between the members, and the like. Furthermore, for example, the transmission electron microscope, X-ray diffraction (XRD), electron beam diffraction (EBD), X-ray photoelectron spectroscopy (XPS), or synchrotron radiation X-ray absorption fine structure (XAFS) can be used to identify crystalline systems of materials forming the members constituting the semiconductor memory device and to compare the abundance ratios of the crystalline systems. Moreover, whether the member constituting the semiconductor memory device is crystalline or amorphous can be determined from, for example, an image obtained by the TEM.

### First Embodiment

A semiconductor memory device according to a first embodiment includes: a semiconductor layer extending in a first direction; a gate electrode layer including at least one metal element selected from a group consisting of tungsten (W), molybdenum (Mo), and cobalt (Co); a charge storage layer provided between the semiconductor layer and the gate electrode layer; and a first insulating layer provided between the charge storage layer and the gate electrode layer, the first insulating layer including a first region, the first region including aluminum (Al) and oxygen (O), the first insulating layer being in contact with the gate electrode layer.

The semiconductor memory device according to the first embodiment is a three-dimensional NAND flash memory. A memory cell of the semiconductor memory device according to the first embodiment is a so-called metal-oxide-nitride-oxide-semiconductor (MONOS) memory cell.

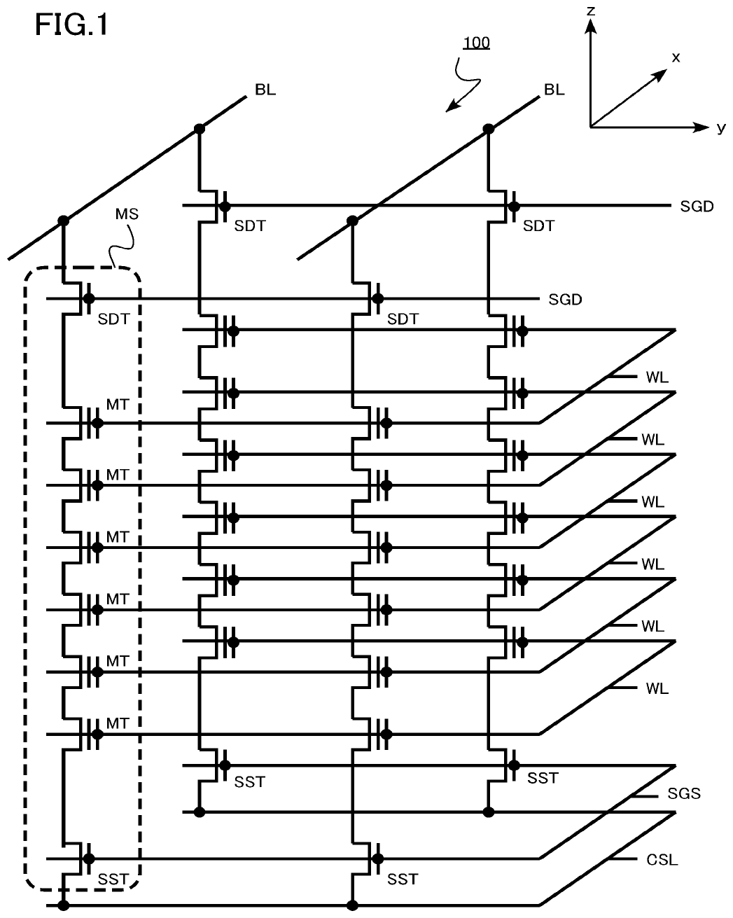

FIG. 1 is a circuit diagram illustrating a memory cell array of the semiconductor memory device according to the first embodiment.

As illustrated in FIG. 1, a memory cell array 100 of the three-dimensional NAND flash memory according to the first embodiment includes a plurality of word lines WL, a common source line CSL, a source select gate line SGS, a plurality of drain select gate lines SGD, a plurality of bit lines BL, and a plurality of memory strings MS.

The plurality of word lines WL are arranged in a z direction to be spaced from each other. The plurality of word lines WL are arranged to be stacked in the z direction. The plurality of memory strings MS extend in the z direction. For example, the plurality of bit lines BL extend in an x direction.

Hereinafter, the x direction is defined as a third direction, a y direction is defined as a second direction, and the z direction is defined as a first direction. The x direction, the y direction, and the z direction intersect each other and are, for example, perpendicular to each other.

As illustrated in FIG. 1, the memory string MS includes a source select transistor SST, a plurality of memory cells, and a drain select transistor SDT that are connected in series between the common source line CSL and the bit line BL. One bit line BL and one drain select gate line SGD can be selected to select one memory string MS, and one word line WL can be selected to select one memory cell. The word line WL is a gate electrode of a memory cell transistor MT constituting the memory cell.

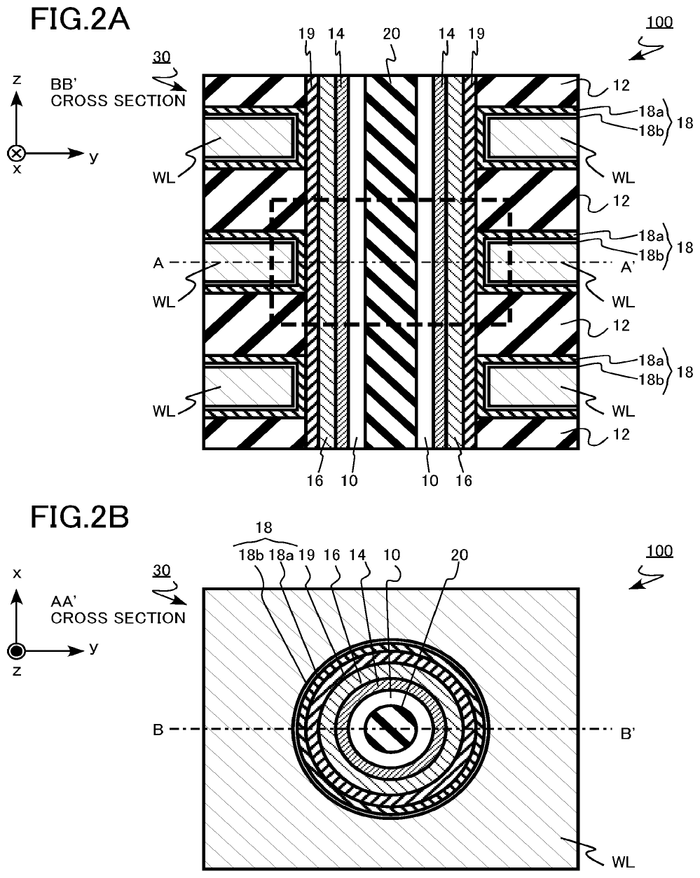

FIGS. 2A and 2B are schematic cross-sectional views illustrating the memory cell array of the semiconductor memory device according to the first embodiment. FIGS. 2A and 2B illustrate, for example, cross sections of a plurality of memory cells in one memory string MS that is surrounded by a dotted line in the memory cell array 100 illustrated in FIG. 1.

FIG. 2A is a yz cross-sectional view illustrating the memory cell array 100. FIG. 2A illustrates a cross section taken along the line B-B′ of FIG. 2B. FIG. 2B is an xy cross-sectional view illustrating the memory cell array 100. FIG. 2B illustrates a cross section taken along the line A-A′ of FIG. 2A. In FIG. 2A, a region surrounded by a broken line is one memory cell.

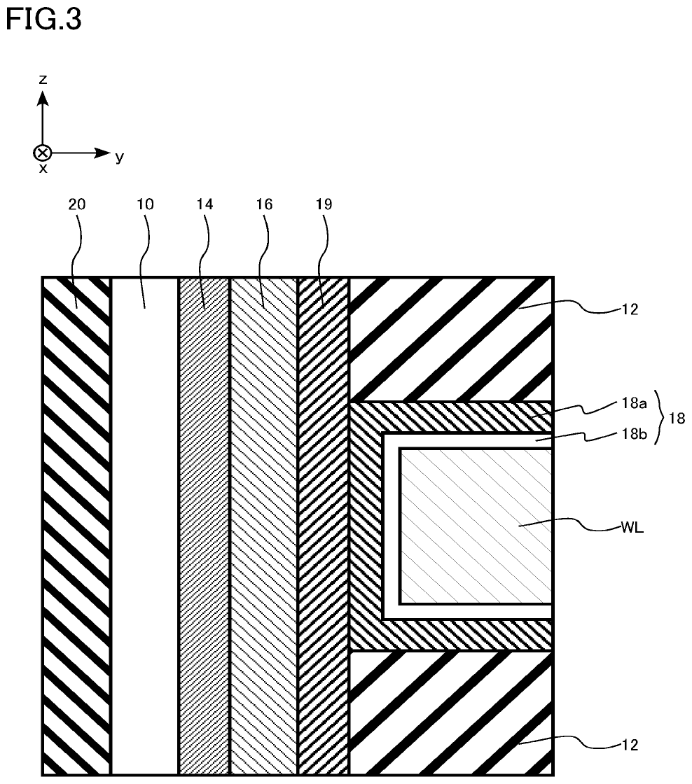

FIG. 3 is a schematic cross-sectional view illustrating the memory cell of the semiconductor memory device according to the first embodiment. FIG. 3 is an enlarged cross-sectional view illustrating a portion of the memory cell.

As illustrated in FIGS. 2A and 2B and FIG. 3, the memory cell array 100 includes the word line WL, a semiconductor layer 10, an interlayer insulating layer 12, a tunnel insulating layer 14, a charge storage layer 16, a first block insulating layer 18, a second block insulating layer 19, and a core insulating region 20.

A plurality of word lines WL and a plurality of interlayer insulating layers 12 constitute a stacked body 30. The first block insulating layer 18 includes a first region 18a and a second region 18b.

The word line WL is an example of a gate electrode layer. The interlayer insulating layer 12 is an example of a fourth insulating layer. The tunnel insulating layer 14 is an example of a third insulating layer. The first block insulating layer 18 is an example of a first insulating layer. The second block insulating layer 19 is an example of a second insulating layer.

The memory cell array 100 is provided, for example, on a semiconductor substrate (not illustrated). The semiconductor substrate has a surface that is parallel to the x direction and the y direction.

The word lines WL and the interlayer insulating layers 12 are alternately stacked on the semiconductor substrate in the z direction. The word lines WL are repeatedly arranged in the z direction to be spaced from each other. The plurality of word lines WL and the plurality of interlayer insulating layers 12 constitute the stacked body 30. The word line WL functions as a control electrode of the memory cell transistor MT.

The word line WL is a plate-shaped conductor. The word line WL includes at least one metal element selected from the group consisting of tungsten (W), molybdenum (Mo), and cobalt (Co). The word line WL is, for example, a tungsten layer, a molybdenum layer, or a cobalt layer. The thickness of the word line WL in the z direction is, for example, equal to or more than 5 nm and equal to or less than 20 nm.

The interlayer insulating layer 12 separates the word lines WL from each other. The interlayer insulating layer 12 electrically separates the word lines WL from each other.

The interlayer insulating layer 12 is, for example, oxide, oxynitride, or nitride. The interlayer insulating layer 12 is, for example, silicon oxide. The thickness of the interlayer insulating layer 12 in the z direction is, for example, equal to or more than 5 nm and equal to or less than 20 nm.

The semiconductor layer 10 is provided in the stacked body 30. The semiconductor layer 10 extends in the z direction. The semiconductor layer 10 extends in a direction perpendicular to the surface of the semiconductor substrate.

The semiconductor layer 10 is provided to penetrate the stacked body 30. The semiconductor layer 10 is surrounded by a plurality of word lines WL. The semiconductor layer 10 has, for example, a cylindrical shape. The semiconductor layer 10 functions as a channel of the memory cell transistor MT.

The semiconductor layer 10 is, for example, a polycrystalline semiconductor. The semiconductor layer 10 is, for example, polycrystalline silicon.

The tunnel insulating layer 14 is provided between the semiconductor layer 10 and the word line WL. The tunnel insulating layer 14 is provided between the semiconductor layer 10 and at least one of the plurality of word lines WL. The tunnel insulating layer 14 is provided between the semiconductor layer 10 and the charge storage layer 16. The tunnel insulating layer 14 has a function of allowing the passage of charge according to a voltage applied between the word line WL and the semiconductor layer 10.

The tunnel insulating layer 14 includes, for example, silicon (Si), nitrogen (N), and oxygen (O). The tunnel insulating layer 14 includes, for example, silicon oxide, silicon nitride, or silicon oxynitride. The tunnel insulating layer 14 is, for example, a stacked structure of a silicon oxide layer, a silicon nitride layer, and a silicon oxide layer. The thickness of the tunnel insulating layer 14 is, for example, equal to or more than 3 nm and equal to or less than 8 nm.

The charge storage layer 16 is provided between the tunnel insulating layer 14 and the first block insulating layer 18. The charge storage layer 16 is provided between the tunnel insulating layer 14 and the second block insulating layer 19.

The charge storage layer 16 has a function of trapping and storing charge. The charge is, for example, an electron. A threshold voltage of the memory cell transistor MT changes depending on the amount of charge stored in the charge storage layer 16. The use of this change in the threshold voltage makes it possible for one memory cell to store data.

For example, when the threshold voltage of the memory cell transistor MT changes, a voltage at which the memory cell transistor MT is turned on changes. For example, when a state in which the threshold voltage is high is defined as data “0” and a state in which the threshold voltage is low is defined as data “1”, the memory cell can store 1-bit data of “0” and “1”.

The charge storage layer 16 is an insulating layer. The charge storage layer 16 includes, for example, silicon (Si) and nitrogen (N). The charge storage layer 16 includes, for example, silicon nitride. The charge storage layer 16 is, for example, a silicon nitride layer. The thickness of the charge storage layer 16 is, for example, equal to or more than 3 nm and equal to or less than 10 nm.

The first block insulating layer 18 and the second block insulating layer 19 are provided between the tunnel insulating layer 14 and the word line WL. The first block insulating layer 18 and the second block insulating layer 19 are provided between the charge storage layer 16 and the word line WL. The first block insulating layer 18 and the second block insulating layer 19 have a function of blocking a current flowing between the charge storage layer 16 and the word line WL.

The thickness of the first block insulating layer 18 in the y direction is, for example, equal to or more than 1 nm and equal to or less than 8 nm. The thickness of the second block insulating layer 19 in the y direction is, for example, equal to or more than 3 nm and equal to or less than 8 nm.

The first block insulating layer 18 is provided between the charge storage layer 16 and the word line WL. The first block insulating layer 18 is provided between the second block insulating layer 19 and the word line WL. The first block insulating layer 18 is in contact with the word line WL.

The interlayer insulating layer 12 is provided in the z direction of the word line WL. The first block insulating layer 18 is provided between the word line WL and the interlayer insulating layer 12 in the z direction.

The first block insulating layer 18 includes the first region 18a and the second region 18b. The second region 18b is provided between the word line WL and the first region 18a.

The first region 18a is an insulating layer. The first region 18a includes aluminum (Al) and oxygen (O). The first region 18a includes aluminum oxide. The first region 18a is, for example, an aluminum oxide layer.

The first region 18a is crystalline. The first region 18a is, for example, a crystalline aluminum oxide layer.

The thickness of the first region 18a in the y direction from the semiconductor layer 10 to the word line WL is, for example, equal to or more than 1 nm and equal to or less than 5 nm.

The second region 18b is an insulating layer. The second region 18b is, for example, oxide, oxynitride, or nitride. The second region 18b includes, for example, at least one of aluminum (Al), hafnium (Hf), or zirconium (Zr). The second region includes, for example, at least one of oxygen (O) or nitrogen (N).

The second region 18b includes, for example, aluminum nitride, aluminum oxynitride, aluminum oxide, aluminum silicate, hafnium silicate, nitrogen-doped hafnium silicate, or zirconium silicate. The second region 18b is, for example, an aluminum nitride layer, an aluminum oxynitride layer, an aluminum oxide layer, an aluminum silicate layer, a hafnium silicate layer, a nitrogen-doped hafnium silicate layer, or a zirconium silicate layer.

The second region 18b is amorphous. The second region 18b is, for example, an amorphous aluminum nitride layer, an amorphous aluminum oxynitride layer, an amorphous aluminum oxide layer, an amorphous aluminum silicate layer, an amorphous hafnium silicate layer, an amorphous nitrogen-doped hafnium silicate layer, or an amorphous zirconium silicate layer.

The second region 18b includes, for example, boron B. The atomic concentration of boron atoms in the second region 18b is, for example, higher than the atomic concentration of boron atoms in the first region 18a.

The second region 18b includes, for example, fluorine (F). The atomic concentration of fluorine atoms in the second region 18b is, for example, higher than the atomic concentration of fluorine atoms in the first region 18a.

The thickness of the second region 18b in the y direction from the semiconductor layer 10 to the word line WL is smaller than the thickness of the first region 18a in the y direction from the semiconductor layer 10 to the word line WL. The thickness of the second region 18b in the y direction from the semiconductor layer 10 to the word line WL is, for example, equal to or more than 0.1 nm and equal to or less than 1 nm.

The second block insulating layer 19 is provided between the charge storage layer 16 and the first block insulating layer 18. The second block insulating layer 19 is provided between the interlayer insulating layer 12 and the semiconductor layer 10. The second block insulating layer 19 is provided between the interlayer insulating layer 12 and the charge storage layer 16.

The second block insulating layer 19 is an insulating layer. The second block insulating layer 19 includes, for example, silicon (Si) and oxygen (O). The second block insulating layer 19 includes, for example, silicon oxide.

The thickness of the second block insulating layer 19 in the y direction is, for example, equal to or more than 3 nm and equal to or less than 8 nm.

The core insulating region 20 is provided in the stacked body 30. The core insulating region 20 extends in the z direction. The core insulating region 20 is provided to penetrate the stacked body 30. The core insulating region 20 is surrounded by the semiconductor layer 10. The core insulating region 20 is surrounded by a plurality of word lines WL. The core insulating region 20 has a columnar shape. The core insulating region 20 has, for example, a cylindrical shape.

The core insulating region 20 is, for example, oxide, oxynitride, or nitride. The core insulating region 20 includes, for example, silicon (Si) and oxygen (O). The core insulating region 20 is, for example, silicon oxide.

Next, an example of a method for manufacturing the semiconductor memory device according to the first embodiment will be described.

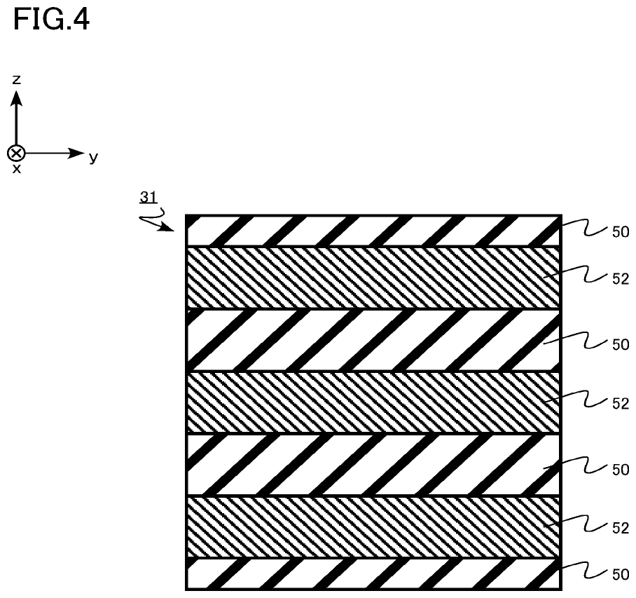

FIGS. 4, 5, 6, 7, 8, 9, 10, 11, 12, 13, and 14 illustrate an example of the method for manufacturing the semiconductor memory device according to the first embodiment. Each of FIGS. 4 to 14 illustrates a cross section corresponding to FIG. 2A. FIGS. 4 to 14 are diagrams illustrating an example of a method for manufacturing the memory cell array 100 of the semiconductor memory device.

First, silicon oxide layers 50 and silicon nitride layers 52 are alternately stacked on a semiconductor substrate (not illustrated) (FIG. 4). A stacked structure 31 in which a plurality of silicon oxide layers 50 and a plurality of silicon nitride layers 52 are alternately stacked in the z direction is formed. A portion of the stacked structure 31 finally becomes the stacked body 30.

The silicon oxide layer 50 and the silicon nitride layer 52 are formed by, for example, a chemical vapor deposition method (CVD method). A portion of the silicon oxide layer 50 finally becomes the interlayer insulating layer 12.

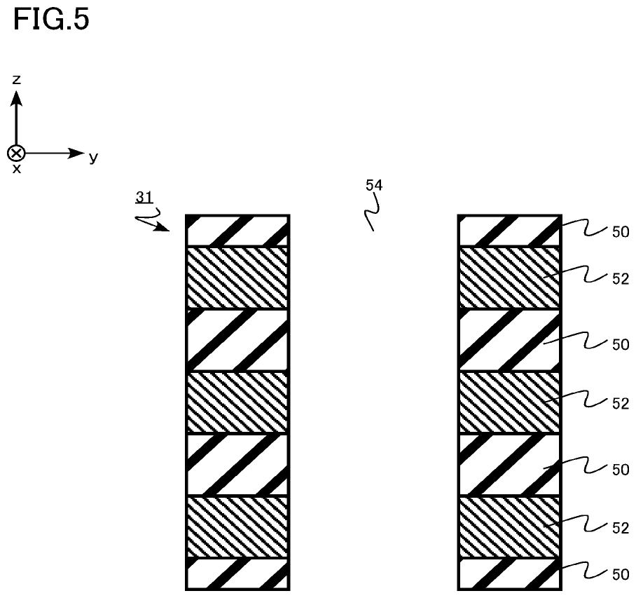

Then, a memory hole 54 is formed in the silicon oxide layer 50 and the silicon nitride layer 52 (FIG. 5). The memory hole 54 penetrates the stacked structure 31 and extends in the z direction. The memory hole 54 is formed by, for example, a lithography method and a reactive ion etching method (RIE method).

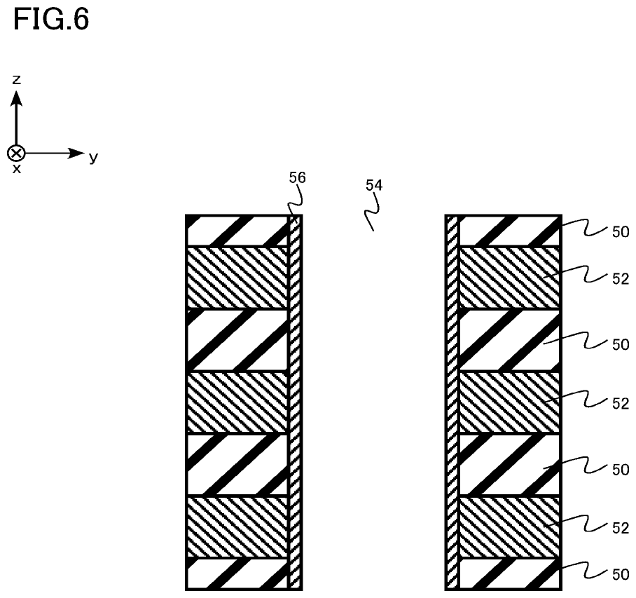

Then, a silicon oxide film 56 is formed on an inner wall of the memory hole 54 (FIG. 6). The silicon oxide film 56 is formed by, for example, the CVD method. The silicon oxide film 56 finally becomes the second block insulating layer 19.

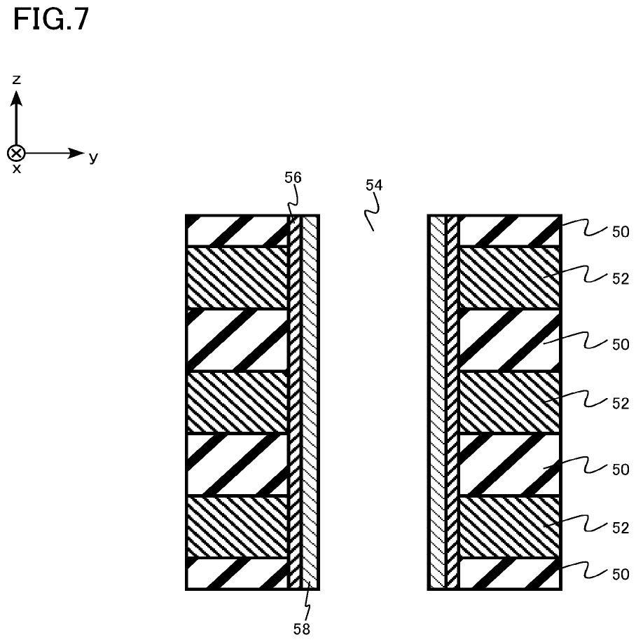

Then, a silicon nitride film 58 is formed on the silicon oxide film 56 (FIG. 7). The silicon nitride film 58 is formed by, for example, an atomic layer deposition method (ALD method). The silicon nitride film 58 finally becomes the charge storage layer 16.

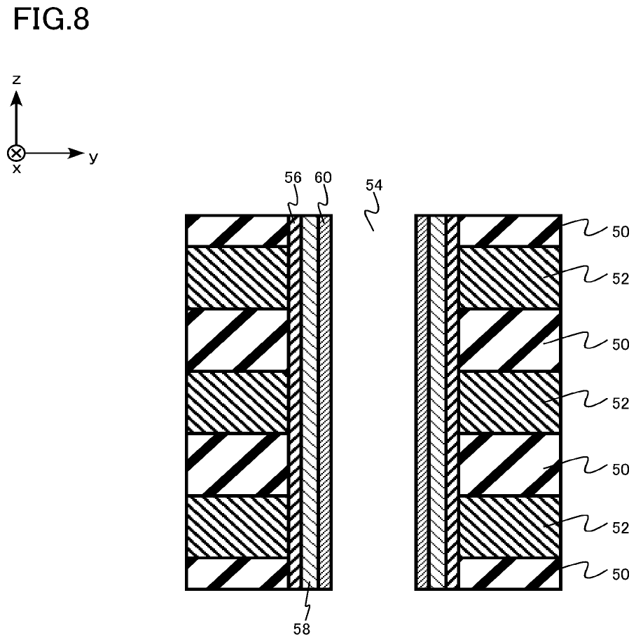

Then, a stacked insulating film 60 is formed on the silicon nitride film 58 (FIG. 8). The stacked insulating film 60 is, for example, a stacked film of a silicon oxide film, a silicon nitride film, and a silicon oxide film.

The stacked insulating film 60 is formed by, for example, the CVD method. The stacked insulating film 60 finally becomes the tunnel insulating layer 14.

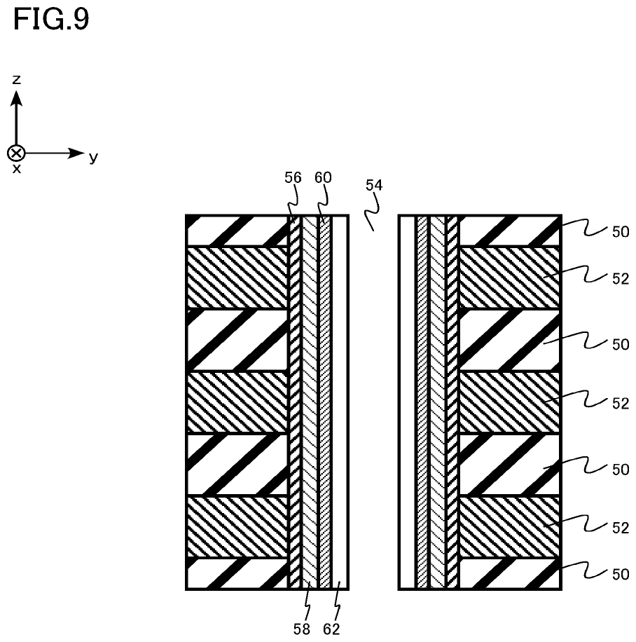

Then, a polycrystalline silicon film 62 is formed on the stacked insulating film 60 (FIG. 9). The polycrystalline silicon film 62 is formed by, for example, the CVD method. The polycrystalline silicon film 62 finally becomes the semiconductor layer 10.

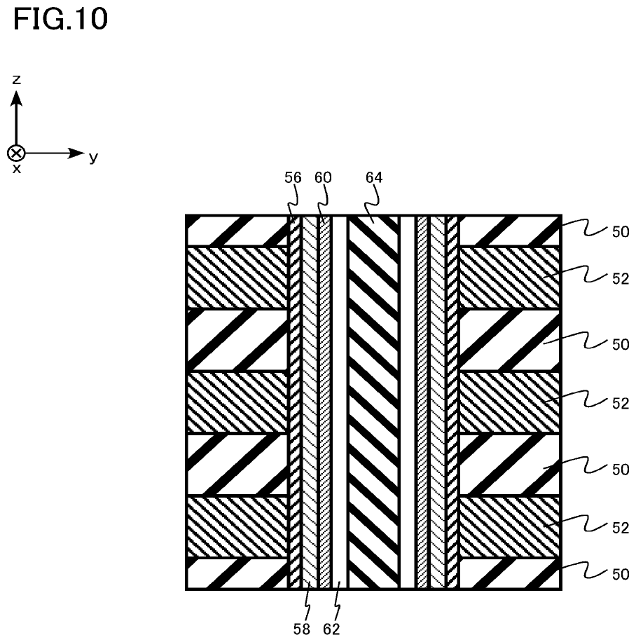

Then, a silicon oxide film 64 is buried in the memory hole 54 (FIG. 10). The silicon oxide film 64 is formed on the polycrystalline silicon film 62. The silicon oxide film 64 is formed by, for example, the CVD method. The silicon oxide film 64 finally becomes the core insulating region 20.

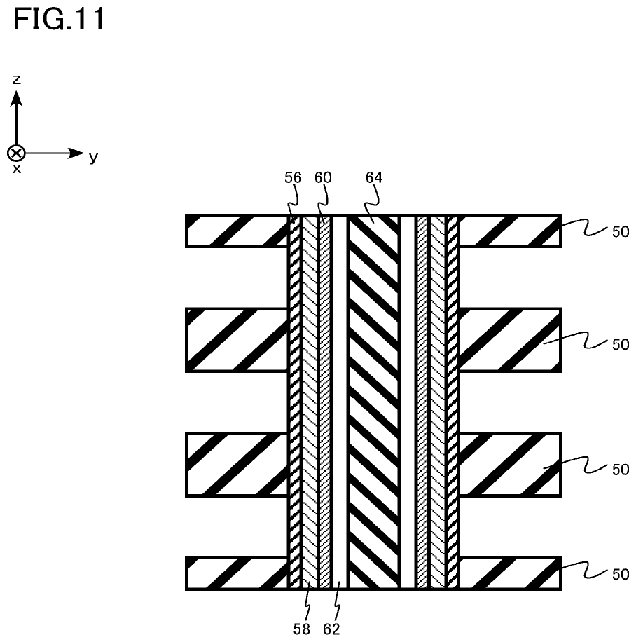

Then, the silicon nitride layer 52 is selectively removed by wet etching using an etching groove (not illustrated) (FIG. 11). For example, a phosphoric acid solution is used for the wet etching. The silicon nitride layer 52 is selectively etched with respect to the silicon oxide layer 50 and the silicon oxide film 56.

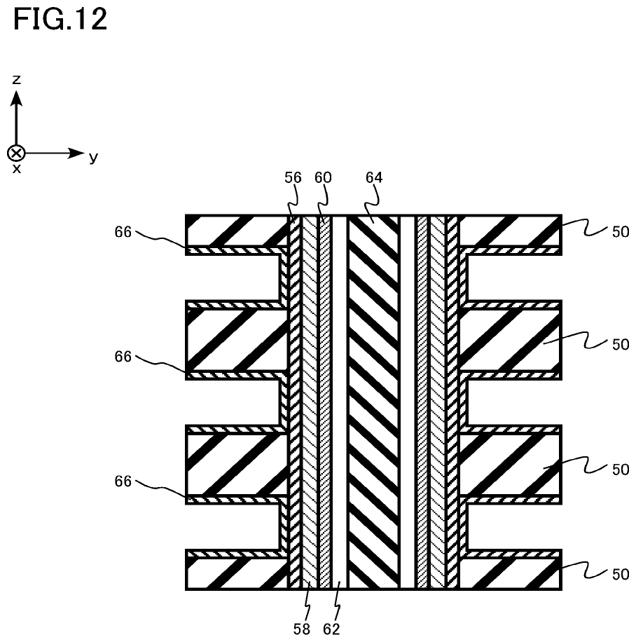

Then, an aluminum oxide film 66 is formed in a region in which the silicon nitride layer 52 has been removed (FIG. 12). The aluminum oxide film 66 is formed by, for example, the ALD method. The aluminum oxide film 66 finally becomes the first region 18a of the first block insulating layer 18.

Then, crystallization annealing is performed. The crystallization annealing is performed, for example, at a temperature of 1000° C. in an inert gas atmosphere. The aluminum oxide film 66 is changed to a crystalline film by the crystallization annealing.

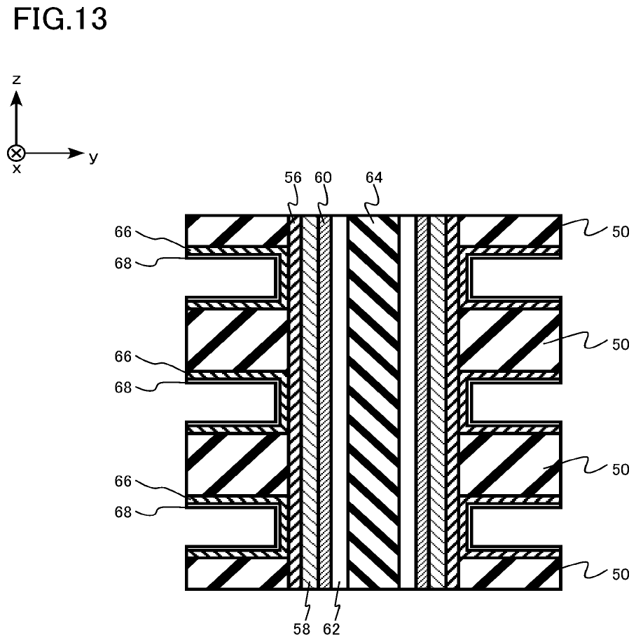

Then, an aluminum nitride film 68 is formed on the aluminum oxide film 66 (FIG. 13).

The aluminum nitride film 68 is formed by, for example, the ALD method.

Further, the aluminum nitride film 68 is formed, for example, by forming an amorphous aluminum oxide film and then performing a nitriding treatment on the amorphous aluminum oxide film. The amorphous aluminum oxide film is formed by, for example, the ALD method. The nitriding treatment is performed by, for example, thermal nitriding or plasma nitriding. The thermal nitriding is performed, for example, in an ammonia atmosphere. The plasma nitriding is performed, for example, in a nitrogen atmosphere.

The aluminum nitride film 68 is amorphous. The aluminum nitride film 68 finally becomes the second region 18b of the first block insulating layer 18.

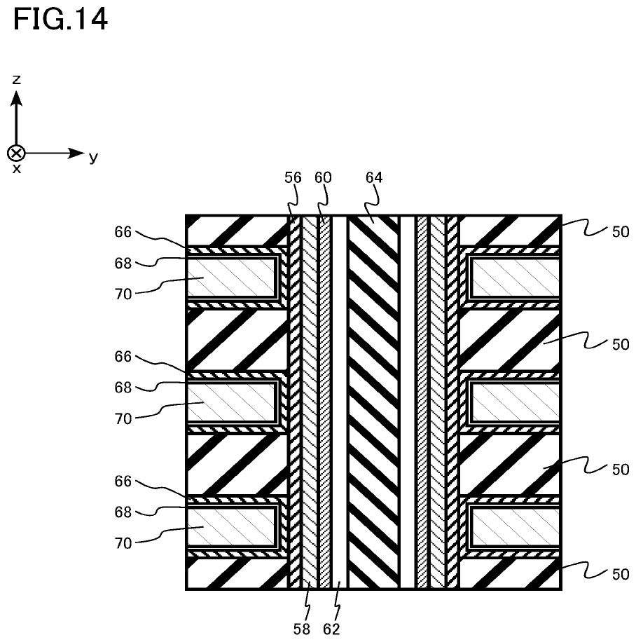

Then, a tungsten film 70 is formed on the aluminum nitride film 68 (FIG. 14). The tungsten film 70 is formed by, for example, the CVD method. The tungsten film 70 finally becomes the word line WL.

When the tungsten film 70 is formed, for example, diborane (B₂H₆) and tungsten hexafluoride (WF₆) are used as source gases.

The memory cell array 100 of the semiconductor memory device according to the first embodiment is manufactured by the above-described manufacturing method.

Next, the function and effect of the semiconductor memory device according to the first embodiment will be described.

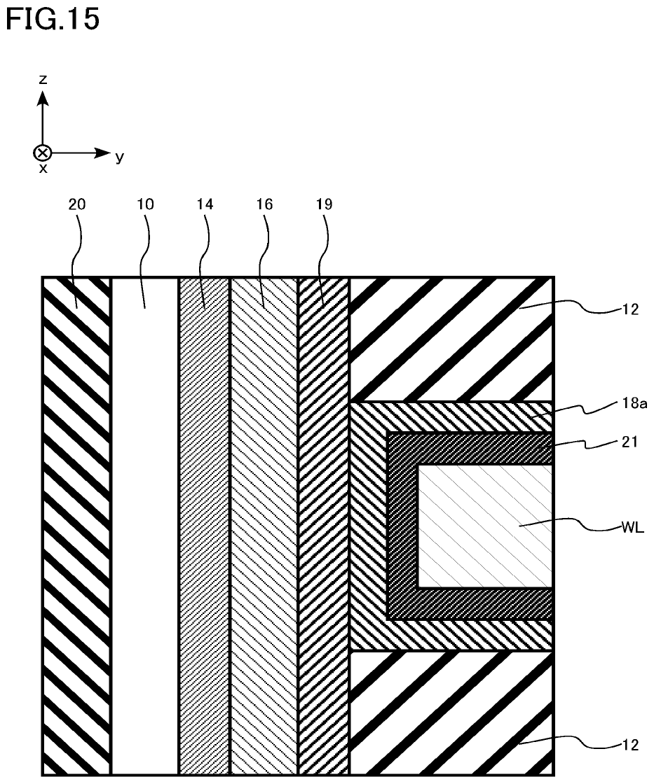

FIG. 15 is a schematic cross-sectional view illustrating a memory cell of a semiconductor memory device according to a comparative example of the first embodiment. FIG. 15 is a diagram corresponding to FIG. 3 illustrating the semiconductor memory device according to the first embodiment.

The semiconductor memory device according to the comparative example differs from the semiconductor memory device according to the first embodiment illustrated in FIG. 3 in that the first block insulating layer 18 does not include the amorphous second region 18b and a barrier metal layer 21 is provided between the first block insulating layer 18 and the word line WL.

The barrier metal layer 21 is a metal layer. The barrier metal layer 21 includes, for example, titanium (Ti) and nitrogen (N). The barrier metal layer 21 includes, for example, titanium nitride. The barrier metal layer 21 is, for example, a titanium nitride layer. The thickness of the barrier metal layer 21 is, for example, equal to or more than 1 nm and equal to or less than 5 nm.

Assuming that the distance between two interlayer insulating layers 12 which face each other in the vertical direction (z direction) is constant, the thickness of the word line WL in the vertical direction is reduced by providing the barrier metal layer 21. In addition, the electrical resistivity of the barrier metal layer 21 is higher than the electrical resistivity of the word line WL.

When the thickness of the word line WL in the vertical direction decreases, the electrical resistance of the word line WL increases. For example, there is a concern that a delay will occur in the operation of the memory cell transistor MT. When a delay occurs in the operation of the memory cell transistor MT, for example, it is difficult to operate a three-dimensional NAND flash memory at a high speed. Therefore, it is desirable to omit the barrier metal layer 21 and to increase the thickness of the word line WL in the vertical direction.

However, the barrier metal layer 21 has a function of suppressing the diffusion of impurities from the word line WL to the charge storage layer 16. When impurities are diffused from the word line WL to the charge storage layer 16, for example, the amount of leakage current between the charge storage layer 16 and the word line WL increases.

When the amount of leakage current between the charge storage layer 16 and the word line WL increases, the characteristics of the memory cell are degraded. When the amount of leakage current between the charge storage layer 16 and the word line WL increases, for example, the charge retention characteristics, erase characteristics, write characteristics, and the like of the memory cell are degraded.

The impurities diffused from the word line WL to the charge storage layer 16 are, for example, boron (B) or fluorine (F) included in the source gas when the word line WL is formed.

The three-dimensional NAND flash memory according to the first embodiment does not include the barrier metal layer provided between the first block insulating layer 18 and the word line WL. Therefore, it is possible to increase the thickness of the word line WL in the vertical direction. As a result, the electrical resistance of the word line WL is reduced, which makes it possible to operate, for example, the three-dimensional NAND flash memory at a high speed.

In addition, in the three-dimensional NAND flash memory according to the first embodiment, the first block insulating layer 18 includes the amorphous second region 18b. Since the three-dimensional NAND flash memory according to the first embodiment includes the amorphous second region 18b, the diffusion of impurities from the word line WL to the charge storage layer 16 is suppressed. Therefore, for example, it is possible to suppress an increase in the amount of leakage current between the charge storage layer 16 and the word line WL. As a result, it is possible to suppress the degradation of the characteristics of the memory cell.

A mechanism in which the diffusion of impurities from the word line WL to the charge storage layer 16 is suppressed by providing the amorphous second region 18b is not necessarily clear. However, for example, it is considered that the amorphous second region 18b serves as an impurity diffusion barrier.

From the viewpoint of suppressing the diffusion of impurities from the word line WL to the charge storage layer 16, the thickness of the second region 18b in the y direction from the semiconductor layer 10 to the word line WL is preferably equal to or more than 0.1 nm and more preferably equal to or more than 0.2 nm.

From the viewpoint of reducing the electrical resistance of the word line WL, it is preferable that the thickness of the second region 18b is small. Therefore, the thickness of the second region 18b in the y direction from the semiconductor layer 10 to the word line WL is preferably equal to or less than 1 nm and more preferably equal to or less than 0.5 nm.

Since the second region 18b suppresses the diffusion of impurities from the word line WL to the charge storage layer 16, the impurity concentration of the second region 18b is higher than the impurity concentration of the first region 18a. For example, the atomic concentration of boron atoms in the second region 18b is higher than the atomic concentration of boron atoms in the first region 18a. In addition, for example, the atomic concentration of fluorine atoms in the second region 18b is higher than the atomic concentration of fluorine atoms in the first region 18a.

As described above, according to the first embodiment, it is possible to provide the semiconductor memory device that includes the word line with reduced resistance and has improved characteristics.

### Second Embodiment

A semiconductor memory device according to a second embodiment includes: a semiconductor layer extending in a first direction; a gate electrode layer including at least one metal element selected from a group consisting of tungsten (W), molybdenum (Mo), and cobalt (Co); a charge storage layer provided between the semiconductor layer and the gate electrode layer; a first insulating layer provided between the charge storage layer and the gate electrode layer, the first insulating layer including a first region and a second region, the first region including aluminum (Al) and oxygen (O), the second region provided between the first region and the gate electrode layer, the first region being crystalline, the second region being amorphous; and a metal layer provided between the first insulating layer and the gate electrode layer, the metal layer being in contact with the second region and the gate electrode layer, the metal layer including titanium (Ti) and nitrogen (N). The semiconductor memory device according to the second embodiment differs from the semiconductor memory device according to the first embodiment in that it includes the metal layer provided between the first insulating layer and the gate electrode layer. Hereinafter, a description of a portion of the content that overlaps that in the first embodiment will be omitted.

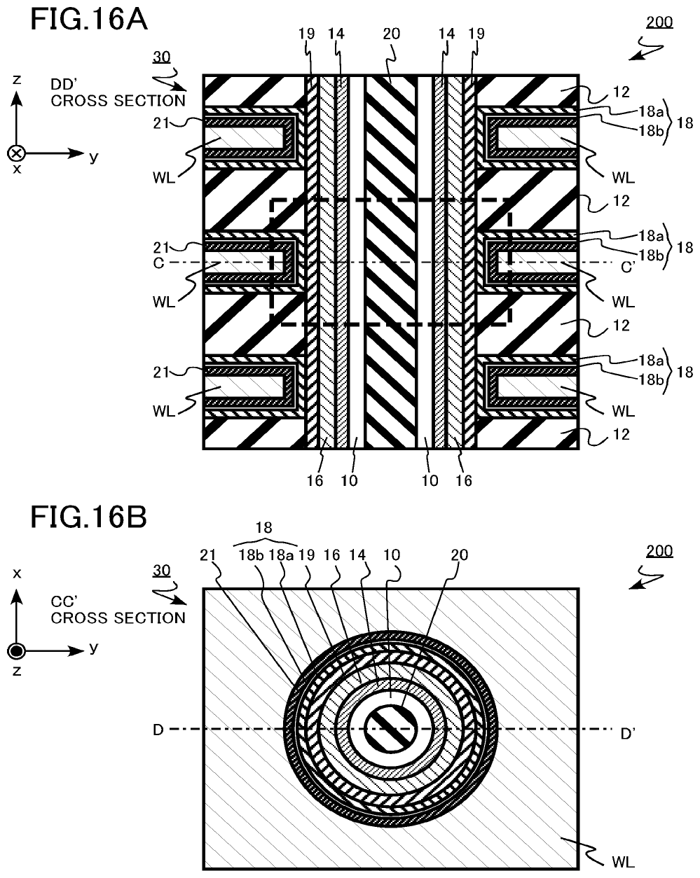

FIGS. 16A and 16B are schematic cross-sectional views illustrating a memory cell array of the semiconductor memory device according to the second embodiment. FIGS. 16A and 16B are diagrams corresponding to FIGS. 2A and (2b) in the first embodiment.

FIG. 16A is a yz cross-sectional view illustrating a memory cell array 200. FIG. 16A illustrates a cross section taken along the line D-D′ of FIG. 16B. FIG. 16B is an xy cross-sectional view illustrating the memory cell array 200. FIG. 16B illustrates a cross section taken along the line C-C′ of FIG. 16A. In FIG. 16A, a region surrounded by a broken line is one memory cell.

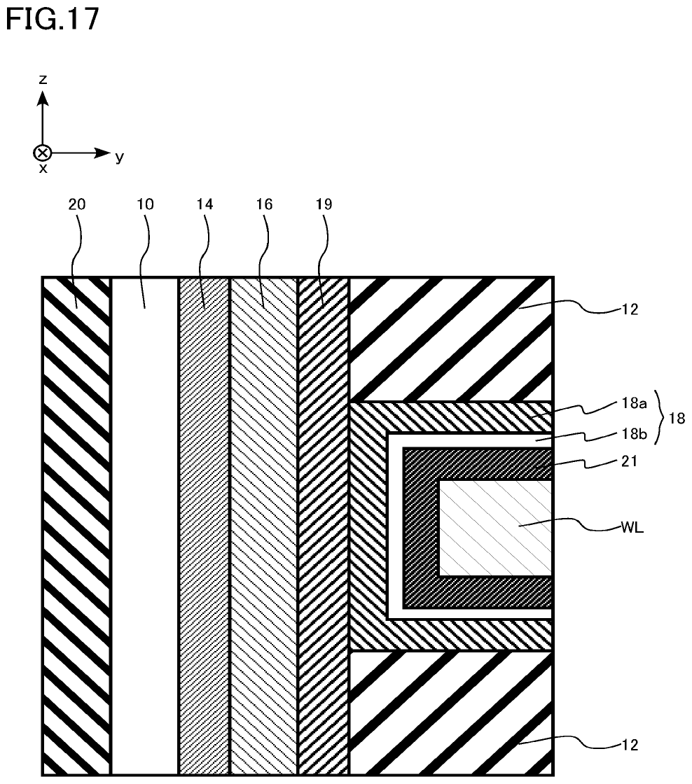

FIG. 17 is a schematic cross-sectional view illustrating a memory cell of the semiconductor memory device according to the second embodiment. FIG. 17 is an enlarged cross-sectional view illustrating a portion of the memory cell.

As illustrated in FIGS. 16A and 16B and FIG. 17, the memory cell array 200 includes a word line WL, a semiconductor layer 10, an interlayer insulating layer 12, a tunnel insulating layer 14, a charge storage layer 16, a first block insulating layer 18, a second block insulating layer 19, a core insulating region 20, and a barrier metal layer 21.

A plurality of word lines WL and a plurality of interlayer insulating layers 12 constitute a stacked body 30. The first block insulating layer 18 includes a first region 18a and a second region 18b.

The word line WL is an example of the gate electrode layer. The interlayer insulating layer 12 is an example of the fourth insulating layer. The tunnel insulating layer 14 is an example of the third insulating layer. The first block insulating layer 18 is an example of the first insulating layer. The second block insulating layer 19 is an example of the second insulating layer. The barrier metal layer 21 is an example of the metal layer.

The first block insulating layer 18 includes the first region 18a and the second region 18b. The Second region 18b is provided between the word line WL and the first region 18a.

The first region 18a is an insulating layer. The first region 18a includes aluminum (Al) and oxygen (O). The first region 18a includes aluminum oxide. The first region 18a is, for example, an aluminum oxide layer.

The first region 18a is crystalline. The first region 18a is, for example, a crystalline aluminum oxide layer.

The thickness of the first region 18a in the y direction from the semiconductor layer 10 to the word line WL is, for example, equal to or more than 1 nm and equal to or less than 5 nm.

The second region 18b is an insulating layer. The second region 18b is, for example, oxide, oxynitride, or nitride. The second region 18b includes at least one of aluminum (Al), hafnium (Hf), or zirconium (Zr). The second region includes, for example, at least one of oxygen (O) or nitrogen (N).

The second region 18b includes, for example, aluminum nitride, aluminum oxynitride, aluminum oxide, aluminum silicate, hafnium silicate, nitrogen-doped hafnium silicate, or zirconium silicate. The second region 18b is, for example, an aluminum nitride layer, an aluminum oxynitride layer, an aluminum oxide layer, an aluminum silicate layer, a hafnium silicate layer, a nitrogen-doped hafnium silicate layer, or a zirconium silicate layer.

The second region 18b is amorphous. The second region 18b is, for example, an amorphous aluminum nitride layer, an amorphous aluminum oxynitride layer, an amorphous aluminum oxide layer, an amorphous aluminum silicate layer, an amorphous hafnium silicate layer, an amorphous nitrogen-doped hafnium silicate layer, or an amorphous zirconium silicate layer.

The second region 18b includes, for example, boron (B). The atomic concentration of boron atoms in the second region 18b is, for example, higher than the atomic concentration of boron atoms in the first region 18a.

The second region 18b includes, for example, fluorine (F). The atomic concentration of fluorine atoms in the second region 18b is, for example, higher than the atomic concentration of fluorine atoms in the first region 18a.

The thickness of the second region 18b in the y direction from the semiconductor layer 10 to the word line WL is smaller than the thickness of the first region 18a in the y direction from the semiconductor layer 10 to the word line WL. The thickness of the second region 18b in the y direction from the semiconductor layer 10 to the word line WL is, for example, equal to or more than 0.1 nm and equal to or less than 1 nm.

The barrier metal layer 21 is provided between the first block insulating layer 18 and the word line WL. The barrier metal layer 21 is provided between the second region 18b and the word line WL. The barrier metal layer 21 is in contact with the second region 18b. The barrier metal layer 21 is in contact with the word line WL.

The barrier metal layer 21 is a metal layer. The barrier metal layer 21 includes, for example, titanium (Ti) and nitrogen (N). The barrier metal layer 21 includes, for example, titanium nitride. The barrier metal layer 21 is, for example, a titanium nitride layer. The thickness of the barrier metal layer 21 is, for example, equal to or more than 1 nm and equal to or less than 5 nm.

Next, an example of a method for manufacturing the semiconductor memory device according to the second embodiment will be described.

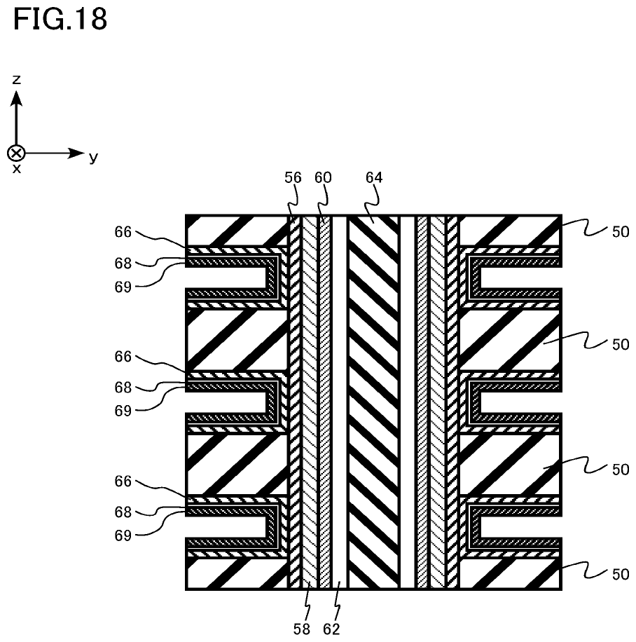

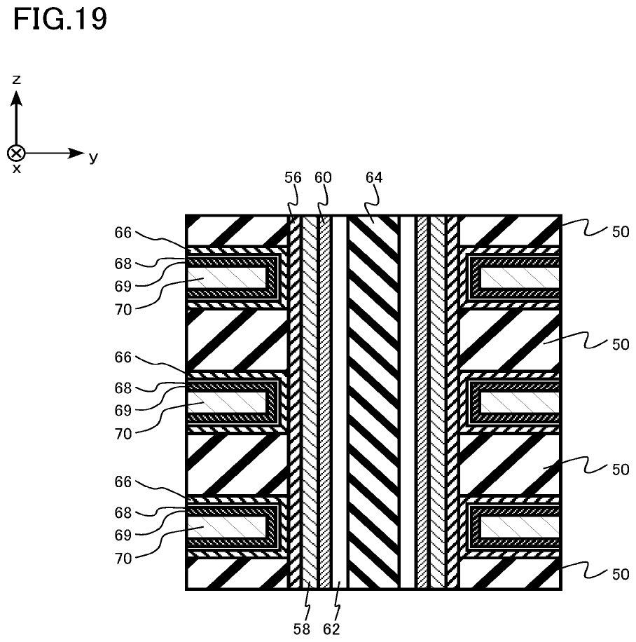

FIGS. 18 and 19 are schematic cross-sectional views illustrating an example of the method for manufacturing the semiconductor memory device according to the second embodiment. Each of FIGS. 18 and 19 illustrates a cross section corresponding to FIG. 16A. FIGS. 18 and 19 are diagrams illustrating an example of a method for manufacturing the memory cell array 200 of the semiconductor memory device.

An example of the method for manufacturing the semiconductor memory device according to the second embodiment is similar to an example of the method for manufacturing the semiconductor memory device according to the second embodiment until an aluminum nitride film 68 is formed on an aluminum oxide film 66.

Then, a titanium nitride film 69 is formed on the aluminum nitride film 68 (FIG. 18). The titanium nitride film 69 is formed by, for example, the ALD method. The titanium nitride film 69 finally becomes the barrier metal layer 21.

Then, a tungsten film 70 is formed on the titanium nitride film 69 (FIG. 19). The tungsten film 70 is formed by, for example, the CVD method. The tungsten film 70 finally becomes the word line WL.

When the tungsten film 70 is formed, for example, diborane (B₂H₆) and tungsten hexafluoride (WF₆) are used as source gases.

Next, the function and effect of the semiconductor memory device according to the second embodiment will be described.

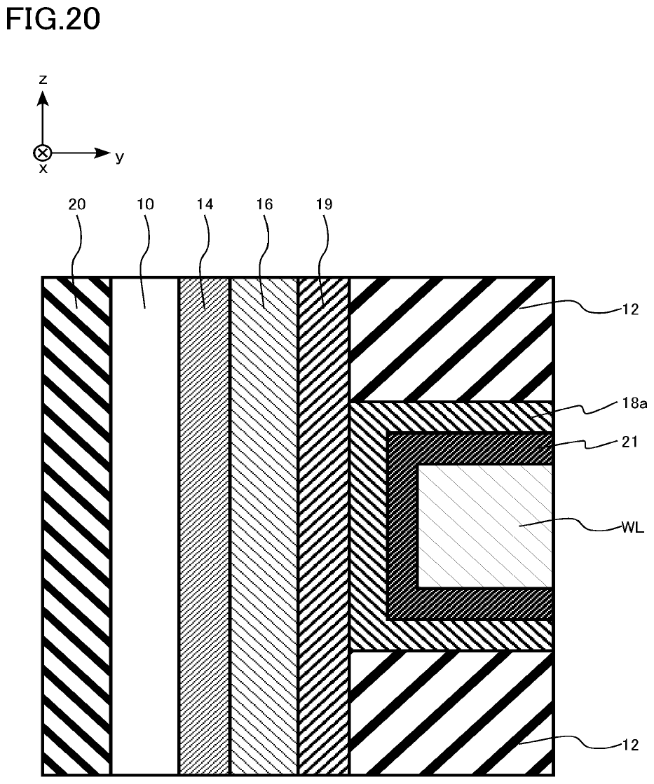

FIG. 20 is a schematic cross-sectional view illustrating a memory cell of a semiconductor memory device according to a comparative example of the second embodiment. FIG. 20 is a diagram corresponding to FIG. 17 illustrating the semiconductor memory device according to the second embodiment.

The semiconductor memory device according to the comparative example differs from the semiconductor memory device according to the second embodiment illustrated in FIG. 17 in that the first block insulating layer 18 does not include the amorphous second region 18b.

The barrier metal layer 21 has a function of suppressing the diffusion of impurities from the word line WL to the charge storage layer 16. In the semiconductor memory device according to the comparative example, in some cases, the effect of suppressing the diffusion of the impurities by the barrier metal layer 21 is insufficient.

Therefore, for example, a problem arises in that the amount of leakage current between the charge storage layer 16 and the word line WL increases. When the amount of leakage current between the charge storage layer 16 and the word line WL increases, the characteristics of the memory cell are degraded. When the amount of leakage current between the charge storage layer 16 and the word line WL increases, for example, the charge retention characteristics, erase characteristics, write characteristics, and the like of the memory cell are degraded.

The impurities diffused from the word line WL to the charge storage layer 16 are, for example, boron (B) or fluorine (F) included in the source gas when the word line WL is formed.

It is considered that the effect of suppressing the diffusion of the impurities by the barrier metal layer 21 is insufficient because the flatness of the barrier metal layer 21 is insufficient.

Since the three-dimensional NAND flash memory according to the second embodiment includes the amorphous second region 18b provided between the first region 18a of the first block insulating layer 18 and the barrier metal layer 21, the diffusion of impurities from the word line WL to the charge storage layer 16 is suppressed. Therefore, for example, it is possible to suppress an increase in the amount of leakage current between the charge storage layer 16 and the word line WL. As a result, it is possible to suppress the degradation of the characteristics of the memory cell.

The flatness of the barrier metal layer 21 is improved by providing the amorphous second region 18b. It is considered that the effect of suppressing the diffusion of the impurities by the barrier metal layer 21 is improved by improving the flatness of the barrier metal layer 21.

It is preferable that the thickness of the second region 18b is large from the viewpoint of improving the flatness of the barrier metal layer 21 to suppress the diffusion of impurities from the word line WL to the charge storage layer 16. Therefore, the thickness of the second region 18b in the y direction from the semiconductor layer 10 to the word line WL is preferably equal to or more than 0.1 nm and more preferably equal to or more than 0.2 nm.

It is preferable that the thickness of the second region 18b is small from the viewpoint of reducing the electrical resistance of the word line WL. Therefore, the thickness of the second region 18b in the y direction from the semiconductor layer 10 to the word line WL is preferably equal to or less than 1 nm and more preferably equal to or less than 0.5 nm.

As described above, according to the second embodiment, it is possible to provide the semiconductor memory device in which the diffusion of impurities from the word line is suppressed and characteristics can be improved.

In the first and second embodiments, the case in which the interlayer insulating layer 12 is provided between the word lines WL has been described as an example. However, the space between the word lines WL may be, for example, a cavity.

In the first and second embodiments, the structure in which the semiconductor layer 10 is surrounded by the word line WL has been described as an example. However, a structure in which the semiconductor layer 10 is interposed between two divided word lines WL can also be adopted. In the case of this structure, it is possible to double the number of memory cells in the stacked body 30.

Further, in the first and second embodiments, the structure in which one semiconductor layer 10 is provided in one memory hole 54 has been described as an example. However, a structure in which a plurality of semiconductor layers, for example, two or more divided semiconductor layers 10 are provided in one memory hole 54 can also be adopted. In the case of this structure, it is possible to more than double the number of memory cells in the stacked body 30.

Furthermore, in the first and second embodiments, the case where the charge storage layer is an insulating layer has been described as an example. However, the charge storage layer may be a conductive layer.

Some embodiments of the invention have been described above. However, these embodiments are presented as examples and are not intended to limit the scope of the invention. These novel embodiments can be carried out in various other forms, and various omissions, substitutions, and changes can be made without departing from the gist of the invention. For example, components of one embodiment may be replaced or modified with components of other embodiments. These embodiments and modifications thereof are included in the scope and gist of the invention and are also included in the scope of the invention described in the claims and equivalents thereto.

While certain embodiments have been described, these embodiments have been presented by way of example only, and are not intended to limit the scope of the inventions. Indeed, the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor layer extending in a first direction;
a gate electrode layer including at least one metal element selected from a group consisting of tungsten (W), molybdenum (Mo), and cobalt (Co);
a charge storage layer provided between the semiconductor layer and the gate electrode layer; and
a first insulating layer provided between the charge storage layer and the gate electrode layer, the first insulating layer including a first region, the first region including aluminum (Al) and oxygen (O), the first insulating layer being in contact with the gate electrode layer.

2. The semiconductor memory device according to claim 1,
wherein the first insulating layer includes a second region provided between the first region and the gate electrode layer, the second region is in contact with the gate electrode layer, and
the first region is crystalline, and the second region is amorphous.

3. The semiconductor memory device according to claim 2,
wherein the second region includes at least one of aluminum (Al), hafnium (Hf), or zirconium (Zr).

4. The semiconductor memory device according to claim 3,
wherein the second region includes at least one of oxygen (O) or nitrogen (N).

5. The semiconductor memory device according to claim 2,
wherein the second region includes at least one of boron (B) or fluorine (F).

6. The semiconductor memory device according to claim 5,
wherein an atomic concentration of boron in the second region is higher than an atomic concentration of boron in the first region, or an atomic concentration of fluorine in the second region is higher than an atomic concentration of fluorine in the first region.

7. The semiconductor memory device according to claim 2,
wherein a thickness of the second region in a second direction from the semiconductor layer to the gate electrode layer is equal to or more than 0.1 nm and equal to or less than 1 nm.

8. The semiconductor memory device according to claim 1,
wherein a thickness of the first region in a second direction from the semiconductor layer to the gate electrode layer is equal to or more than 1 nm and equal to or less than 5 nm.

9. The semiconductor memory device according to claim 1, further comprising:
a second insulating layer provided between the charge storage layer and the first insulating layer, the second insulating layer including silicon (Si) and oxygen (O).

10. The semiconductor memory device according to claim 1, further comprising:
a third insulating layer provided between the charge storage layer and the semiconductor layer.

11. The semiconductor memory device according to claim 1, further comprising:
a fourth insulating layer provided in the first direction of the gate electrode layer, the first insulating layer provided between the fourth insulating layer and the gate electrode layer.

12. A semiconductor memory device comprising:
a semiconductor layer extending in a first direction;
a gate electrode layer including at least one metal element selected from a group consisting of tungsten (W), molybdenum (Mo), and cobalt (Co);
a charge storage layer provided between the semiconductor layer and the gate electrode layer;
a first insulating layer provided between the charge storage layer and the gate electrode layer, the first insulating layer including a first region and a second region, the first region including aluminum (Al) and oxygen (O), the second region provided between the first region and the gate electrode layer, the first region being crystalline, the second region being amorphous; and
a metal layer provided between the first insulating layer and the gate electrode layer, the metal layer being in contact with the second region and the gate electrode layer, the metal layer including titanium (Ti) and nitrogen (N).

13. The semiconductor memory device according to claim 12,
wherein the second region includes at least one of aluminum (Al), hafnium (Hf), or zirconium (Zr).

14. The semiconductor memory device according to claim 13,
wherein the second region includes at least one of oxygen (O) or nitrogen (N).

15. The semiconductor memory device according to claim 12,
wherein a thickness of the second region in a second direction from the semiconductor layer to the gate electrode layer is equal to or more than 0.1 nm and equal to or less than 1 nm.

16. The semiconductor memory device according to claim 12,
wherein a thickness of the first region in a second direction from the semiconductor layer to the gate electrode layer is equal to or more than 1 nm and equal to or less than 5 nm.

17. The semiconductor memory device according to claim 12, further comprising:
a second insulating layer provided between the charge storage layer and the first insulating layer, the second insulating layer including silicon (Si) and oxygen (O).

18. The semiconductor memory device according to claim 12, further comprising:
a third insulating layer provided between the charge storage layer and the semiconductor layer.

19. The semiconductor memory device according to claim 12, further comprising:
a fourth insulating layer provided in the first direction of the gate electrode layer, the first insulating layer provided between the fourth insulating layer and the gate electrode layer.

20. The semiconductor memory device according to claim 12,
wherein a thickness of the metal layer in a second direction from the semiconductor layer to the gate electrode layer is equal to or more than 1 nm and equal to or less than 5 nm.
